(19) United States
(12) Patent Application Publication
(10) Pub. No.: US 2025/0338576 A1
(43) Pub. Date: Oct. 30, 2025

(54) SEMICONDUCTOR STRUCTURE AND METHOD FOR MANUFACTURING THEREOF

(71) Applicant: ENKRIS SEMICONDUCTOR, INC., Suzhou (CN)

(72) Inventors: Guoqiao TAO, Suzhou (CN); Kai CHENG, Suzhou (CN)

(21) Appl. No.: 19/091,524

(22) Filed: Mar. 26, 2025

(30) Foreign Application Priority Data
Apr. 25, 2024 (CN) 202410508498.6

(51) Int. Cl. H10D 62/10; H10D 30/01; H10D 30/47; H10D 62/40; H10D 62/815; H10D 62/85

(52) U.S. Cl. CPC H10D 62/125; H10D 30/015; H10D 30/475; H10D 62/405; H10D 62/8164; H10D 62/8503

(57) ABSTRACT

A semiconductor structure includes a substrate and a channel structure on the substrate. The channel structure includes a gate region, and a source region and a drain region at both sides of the gate region. The source region is provided with a first groove, the drain region is provided with a second groove, and a bottom surface of the first groove and a bottom surface of the second groove are respectively lower than a surface of the channel layer away from the substrate. The first groove is filled with a first N-type heavily doped layer, the second groove is filled with a second N-type heavily doped layer, and in a direction away from the substrate, distances between a first sidewall of the first N-type heavily doped layer toward the gate region and a second sidewall of the second N-type heavily doped layer toward the gate region gradually increase.

### CROSS REFERENCE TO RELATED APPLICATIONS

This application claims priority to Chinese Patent Application No. 2024105084986 entitled “SEMICONDUCTOR STRUCTURE AND METHOD FOR MANUFACTURING THEREOF” filed on Apr. 25, 2024, the entire content of which is incorporated herein by reference.

### TECHNICAL FIELD

The present disclosure relates to the technical field of semiconductors, in particular to a semiconductor structure and a method for manufacturing thereof.

### BACKGROUND

During a manufacturing process of a GaN-based high electron mobility transistor (HEMT) device, the ohmic contact process of the source electrode/drain electrode is one of the key technologies, which directly affects the performance of the device, such as, the frequency and the power. In recent years, secondary epitaxial growth of N-type heavily doped layers in ohmic contact regions to reduce ohmic contact resistivity and improve surface morphology has become a new process internationally. This process can realize the non-alloy ohmic contact, greatly improve the morphology of the ohmic contact surfaces and ohmic contact edges, and realize the self-aligned process of the source electrode/drain electrode/gate electrode. The N-type heavily doped layer grown by secondary epitaxy may be implemented by molecular beam epitaxy (MBE), or may be implemented by metal organic chemical vapor deposition (MOCVD). The ohmic contact resistance realized by this process mainly includes a contact resistance between the metal and the N-type heavily doped layer, and a contact resistance between the N-type heavily doped layer and the sidewall of the GaN-based heterojunction. The contact status between the N-type heavily doped layer and the sidewall of the GaN-based heterojunction directly affects the contact resistance between the N-type heavily doped layer and the sidewall of the GaN-based heterojunction, and this contact resistance has the greatest influence on the overall ohmic contact resistance. Therefore, effectively reducing the contact resistance between the N-type heavily doped layer and the sidewall of the GaN-based heterojunction is of great significance for reducing the overall ohmic contact.

### SUMMARY

In view of this, according to the present disclosure, a semiconductor structure and a manufacturing method thereof are provided, to solve the problem of excessive contact resistance of a semiconductor device.

According to a first aspect, the present disclosure provides a semiconductor structure. The semiconductor structure includes a substrate and a channel structure on the substrate. The channel structure includes a channel layer on the substrate and a barrier layer on the channel layer, and the channel structure includes a gate region, and a source region and a drain region at both sides of the gate region. The source region is provided with a first groove, the drain region is provided with a second groove, and a bottom surface of the first groove and a bottom surface of the second groove are lower than a surface of the channel layer away from the substrate. The first groove is filled with a first N-type heavily doped layer, the second groove is filled with a second N-type heavily doped layer, and in a direction away from the substrate, distances between a first sidewall of the first N-type heavily doped layer toward the gate region and a second sidewall of the second N-type heavily doped layer toward the gate region gradually increase.

In some embodiments of the present disclosure, the first N-type heavily doped layer includes a third sidewall away from the gate region, and the second N-type heavily doped layer includes a fourth sidewall away from the gate region; where in the direction away from the substrate, distances between the third sidewall and the fourth sidewall gradually decrease.

In some embodiments of the present disclosure, the third sidewall and the fourth sidewall are respectively rough surfaces.

In some embodiments of the present disclosure, the semiconductor structure further includes: a gate electrode at a side of the barrier layer away from the substrate; a source electrode electrically connected to the third sidewall; and a drain electrode electrically connected to the fourth sidewall.

In some embodiments of the present disclosure, each of the first sidewall and the second sidewall is configured as an inclined flat surface, a convex curved surface, or a concave curved surface.

In some embodiments of the present disclosure, the first sidewall and the second sidewall are respectively rough surfaces.

In some embodiments of the present disclosure, the semiconductor structure further includes: a gate electrode, at a side of the barrier layer away from the substrate; a source electrode, electrically connected to a first surface of the first N-type heavily doped layer away from the substrate; and a drain electrode, electrically connected to a second surface of the second N-type heavily doped layer away from the substrate; where the first surface and the second surface are rough surfaces.

In some embodiments of the present disclosure, the first N-type heavily doped layer and the second N-type heavily doped layer each includes an N-type heavily doped GaN-based material layer or an N-type heavily doped GaN-based superlattice structure.

In some embodiments of the present disclosure, the first sidewall is axially symmetrical to the second sidewall, and the first N-type heavily doped layer is axially symmetrical to the second N-type heavily doped layer.

In some embodiments of the present disclosure, in the direction away from the substrate, widths of a cross section of the first N-type heavily doped layer perpendicular to a channel length direction gradually increase; and/or in the direction away from the substrate, widths of a cross section of the second N-type heavily doped layer perpendicular to the channel length direction gradually increase.

In some embodiments of the present disclosure, a gradual increase of the widths of the cross section of the first N-type heavily doped layer perpendicular to the channel length direction includes a linear increase, a curvilinear increase or a stepped increase; and/or a gradual increase of the widths of the cross section of the second N-type heavily doped layer perpendicular to the channel length direction includes a linear increase, a curvilinear increase or a stepped increase.

In some embodiments of the present disclosure, the semiconductor structure includes a plurality of channel structures stacked on the substrate sequentially, and the bottom surface of the first groove and the bottom surface of the second groove are respectively lower than a surface of a channel layer away from the substrate in a channel structure closest to the substrate.

In some embodiments of the present disclosure, in the direction away from the substrate, average Al contents of barrier layers in the plurality of channel structures gradually decrease.

In some embodiments of the present disclosure, the first N-type heavily doped layer and the second N-type heavily doped layer are made of GaN-based materials, and crystal plane indices of the first sidewall and the second sidewall each independently includes at least one of (112 3̅), (112 2̅), (112 1̅), (101 2̅), (101 1̅) or (202 1̅).

According to a second aspect, the present disclosure provides a method for manufacturing a semiconductor structure, where the method includes: providing a substrate; forming a channel structure on the substrate, where forming the channel structure includes forming a channel layer on the substrate and forming a barrier layer on the channel layer, and the channel structure includes a gate region, and a source region and a drain region at both sides of the gate region; forming a first groove and a second groove respectively in the source region and the drain region, where a bottom surface of the first groove and a bottom surface of the second groove are respectively lower than a surface of the channel layer away from the substrate; and in a direction away from the substrate, distances between a first inner wall of the first groove toward the gate region and a second inner wall of the second groove toward the gate region gradually increase; and filling the first groove and the second groove with a first N-type heavily doped layer and a second N-type heavily doped layer respectively, where in the direction away from the substrate, distances between a first sidewall of the first N-type heavily doped layer toward the gate region and a second sidewall of the second N-type heavily doped layer toward the gate region gradually increase.

In some embodiments of the present disclosure, the method further includes: etching the first N-type heavily doped layer and the second N-type heavily doped layer to form a third sidewall of the first N-type heavily doped layer away from the gate region and a fourth sidewall of the second N-type heavily doped layer away from the gate region, where in the direction away from the substrate, distances between the third sidewall and the fourth sidewall gradually decrease; forming a gate electrode at a side of the barrier layer away from the substrate; and forming a source electrode electrically connected to the third sidewall and a drain electrode electrically connected to the fourth sidewall.

In some embodiments of the present disclosure, after etching the first N-type heavily doped layer and the second N-type heavily doped layer, the method further includes: roughening the third sidewall and the fourth sidewall.

In some embodiments of the present disclosure, a first surface of the first N-type heavily doped layer away from the substrate is a rough surface, and a second surface of the second N-type heavily doped layer away from the substrate is a rough surface, and the method further includes: forming a gate electrode at a side of the barrier layer away from the substrate; and forming a source electrode electrically connected to the first surface and a drain electrode electrically connected to the second surface.

In some embodiments of the present disclosure, forming the first groove and the second groove respectively in the source region and the drain region includes respectively forming the first groove and the second groove each having a cross section perpendicular to a channel length direction whose widths gradually increase in the direction away from the substrate; and filling the first groove and the second groove with the first N-type heavily doped layer and the second N-type heavily doped layer respectively includes forming the first N-type heavily doped layer and/or the second N-type heavily doped layer, where widths of a cross section of the first N-type heavily doped layer perpendicular to the channel length direction and widths of a cross section of the second N-type heavily doped layer perpendicular to the channel length direction gradually increase respectively.

In some embodiments of the present disclosure, forming the channel structure on the substrate includes: forming a plurality of channel structures stacked on the substrate sequentially; and forming the first groove and the second groove respectively in the source region and the drain region includes: etching the plurality of channel structures until that the bottom surface of the first groove and the bottom surface of the second groove are respectively lower than a surface of the channel layer away from the substrate in a channel structure closest to the substrate.

Embodiments of the present disclosure provide a semiconductor structure and a method for manufacturing thereof, and by slanting the first sidewall and the second sidewall, the contact resistance between the first N-type heavily doped layer and the two-dimensional electron gas of the channel structure, and the contact resistance between the second N-type heavily doped layer and the two-dimensional electron gas of the channel structure can be reduced.

### BRIEF DESCRIPTION OF DRAWINGS

FIG. 1 is a schematic diagram of a cross section of a semiconductor structure according to an embodiment of the present disclosure.

FIG. 2 is a schematic diagram of a cross section of another semiconductor structure according to an embodiment of the present disclosure.

FIG. 3 is a schematic diagram of a cross section of another semiconductor structure according to an embodiment of the present disclosure.

FIG. 4 is a schematic diagram of a cross section of another semiconductor structure according to an embodiment of the present disclosure.

FIG. 5 is a schematic diagram of a cross section of another semiconductor structure according to an embodiment of the present disclosure.

FIG. 6 is a schematic diagram of a cross section of another semiconductor structure according to an embodiment of the present disclosure.

FIG. 7 is a schematic diagram of a cross section of another semiconductor structure according to an embodiment of the present disclosure.

FIG. 8 is a schematic diagram of a cross section of another semiconductor structure according to an embodiment of the present disclosure.

FIG. 9 is a schematic diagram of a cross section of another semiconductor structure according to an embodiment of the present disclosure.

FIG. 10 is a schematic diagram of a cross section of another semiconductor structure according to an embodiment of the present disclosure.

FIG. 11 is a schematic diagram of a cross section of another semiconductor structure according to an embodiment of the present disclosure.

FIG. 12 is a schematic diagram of a rough surface according to an embodiment of the present disclosure.

FIG. 13 is a schematic diagram of another rough surface according to an embodiment of the present disclosure.

FIG. 14 is a schematic diagram of a cross-section along line AB in FIGS. 4 to 6.

FIG. 15 is a schematic diagram of a cross section of another semiconductor structure according to an embodiment of the present disclosure.

FIG. 16 is a schematic diagram of a cross section of another semiconductor structure according to an embodiment of the present disclosure.

FIG. 17 is a schematic diagram of a cross-section along the line CD in FIG. 15.

FIG. 18 is a flowchart of a method for manufacturing a semiconductor structure according to an embodiment of the present disclosure.

FIG. 19 is a schematic diagram of a cross section for an intermediate structure of a method for manufacturing a semiconductor structure according to an embodiment of the present disclosure.

FIG. 20 is a schematic diagram of a cross section for an intermediate structure of a method for manufacturing a semiconductor structure according to an embodiment of the present disclosure.

FIG. 21 is a schematic diagram of a cross section for an intermediate structure of a method for manufacturing a semiconductor structure according to an embodiment of the present disclosure.

FIG. 22 is a schematic diagram of a cross section for an intermediate structure of a method for manufacturing a semiconductor structure according to an embodiment of the present disclosure.

FIG. 23 is a schematic diagram of a cross section for an intermediate structure of a method for manufacturing a semiconductor structure according to an embodiment of the present disclosure.

### DESCRIPTION OF REFERENCE NUMERALS

10—substrate; 20—channel structure; 11—gate region; 12—source region; 13—drain region; 21—channel layer; 22—barrier layer; 30—first groove; 31—first inner wall; 40—second groove; 41—second inner wall; 50—first N—type heavily doped layer; 51—first sidewall; 52—third sidewall; 53—first surface; 60—second N—type heavily doped layer; 61—second sidewall; 62—fourth sidewall; 63—second surface; 70—gate electrode; 71—gate dielectric layer; 72—P-type GaN layer; 80—source electrode; 90—drain electrode.

### DETAILED DESCRIPTION

In order to make those skilled in the art better understand the solutions of the present disclosure, the technical solutions in the embodiments of the present disclosure will be clearly and completely described below with reference to the accompanying drawings in the embodiments of the present disclosure. Obviously, the described embodiments are only a portion of embodiments of the present disclosure and not all embodiments of the present disclosure. It should be understood that the terms first, second, etc. used in the present disclosure are merely used to distinguish information of a same type from each other, and are not necessarily used to describe a specific order or sequence.

High electron mobility transistor (HEMT) devices exhibit excellent performance in terms of the high breakdown voltage, the low conduction resistance, and the immunity of the hot carrier. However, the ohmic contact resistance in the high electron mobility transistors needs to be improved, to further improve the microwave and high frequency (terahertz) characteristics of the HEMT.

To resolve a problem that a contact resistance of a semiconductor device is excessively high, the present disclosure provides a semiconductor structure, to improve the performance of the semiconductor device. A semiconductor structure for a high electron mobility transistor device will be described below as an example.

In the drawings of the present disclosure, a direction parallel to both the substrate and the channel length direction of the semiconductor structure is taken as the X-axis, a direction parallel to the substrate and perpendicular to the channel length direction of the semiconductor structure is taken as the Y-axis, and a direction perpendicular to the substrate is taken as the Z-axis.

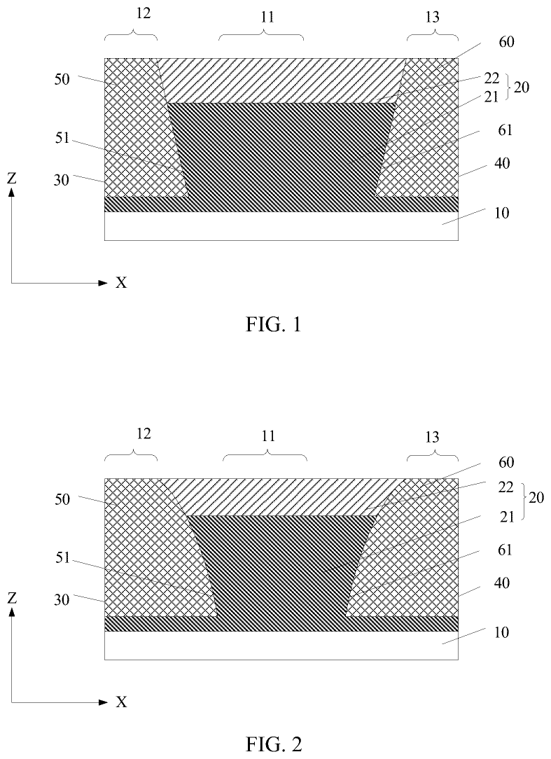

FIG. 1 is a schematic diagram of a cross section of a semiconductor structure according to an embodiment of the present disclosure. As shown in FIG. 1, a semiconductor structure according to an embodiment of the present disclosure includes a substrate 10 and a channel structure 20 on the substrate 10.

The channel structure 20 includes a channel layer 21 on the substrate 10 and a barrier layer 22 on the channel layer 21. The channel structure 20 includes a gate region 11, and a source region 12 and a drain region 13 at both sides of the gate region 11.

Optionally, a buffer layer (not shown) may be further disposed between the channel structure 20 and the substrate 10. The buffer layer may reduce the dislocation density and the defect density of the semiconductor layer epitaxially grown thereon, and improve the crystal quality.

The source region 12 is provided with a first groove 30, the drain region 13 is provided with a second groove 40, and a bottom surface of the first groove 30 and a bottom surface of the second groove 40 are respectively lower than a surface of the channel layer 21 away from the substrate 10. The first groove 30 is filled with a first N-type heavily doped layer 50, the second groove 40 is filled with a second N-type heavily doped layer 60, and in a direction away from the substrate 10, distances between a first sidewall 51 of the first N-type heavily doped layer 50 toward the gate region 11 and a second sidewall 61 of the second N-type heavily doped layer 60 toward the gate region 11 gradually increase. That is, in the direction away from the substrate 10, the first sidewall 51 and the second sidewall 61 are both flat surfaces slanting toward a direction away from the gate region 11. That is, in the cross section where the X-axis and the Z-axis are located, the channel structure 20 is a trapezoid that is wide at the top and narrow at the bottom. The angle between the first sidewall 51 and the plane where the substrate 10 is located and the angle between the second sidewall 61 and the plane where the substrate 10 is located may range from 40 degrees to 89 degrees, for example, 85 degrees, 80 degrees, 75 degrees, 70 degrees or 65 degrees.

In this embodiment, the contact resistance of the semiconductor structure includes a contact resistance R1a between the first N-type heavily doped layer 50 and the channel structure 20 and a contact resistance R1b between the second N-type heavily doped layer 60 and the channel structure 20.

In the present disclosure, the slanted first sidewall 51 and the slanted second sidewall 61 are disposed, so that a contact area between the first N-type heavily doped layer 50 and the channel structure 20 and a contact area between the second N-type heavily doped layer 60 and the channel structure 20 can be increased without increasing an overall thickness of the semiconductor structure. Further, a contact area between the two-dimensional electron gas (2 DEG) and the first N-type heavily doped layer 50 and a contact area between the two-dimensional electron gas and the second N-type heavily doped layer 60 are increased. Because a larger contact area between two objects indicates a smaller contact resistance between the two objects, increasing the contact area between the two-dimensional electron gas (2 DEG) and the first N-type heavily doped layer 50 and the contact area between the two-dimensional electron gas and the second N-type heavily doped layer 60 can reduce the contact resistance R1a between the first N-type heavily doped layer 50 and the two-dimensional electron gas and the contact resistance Rib between the second N-type heavily doped layer 60 and the two-dimensional electron gas, thereby reducing the overall contact resistance in the semiconductor structure.

In addition, as shown in FIG. 1, in the direction away from the substrate 10, the distances between the first sidewall 51 and the second sidewall 61 gradually increase, that is, in the direction away from the substrate 10, the lengths of the channel of the semiconductor structure gradually increase, that is, the closer to the substrate 10, the shorter the length of the channel of the semiconductor structure. Compared with a semiconductor structure in which the first sidewall 51 and the second sidewall 61 are not obliquely disposed, in the present disclosure, the channel structure is partially replaced with the first N-type heavily doped layer 50 and the second N-type heavily doped layer 60 that have relatively low body resistance, so that, the overall body resistance is decreased, and the ohmic contact resistance between the first N-type heavily doped layer 50 and the electrode and the ohmic contact resistance between the second N-type heavily doped layer 60 and the electrode are further reduced, thereby improving the performance of the semiconductor structure.

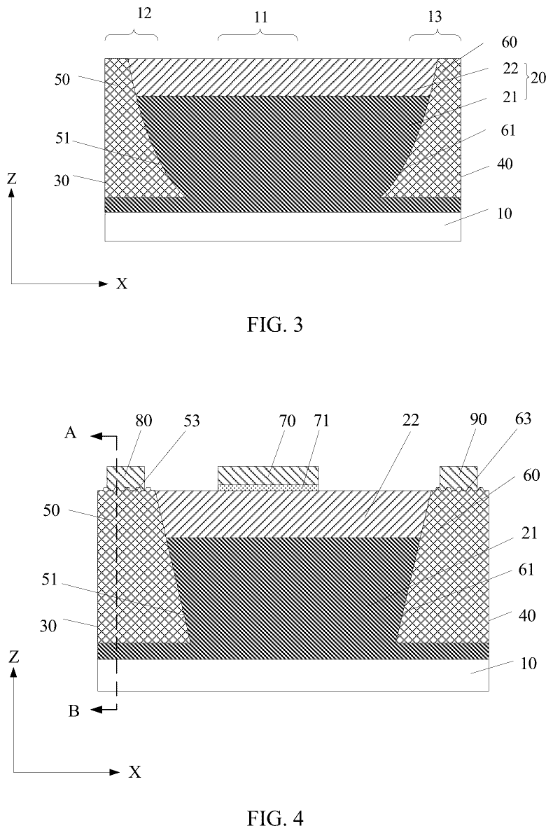

In some embodiments of the present disclosure, the first sidewall 51 and the second sidewall 61 may be respectively curved surfaces. Optionally, as shown in FIG. 2, the first sidewall 51 and the second sidewall 61 may be convex curved surfaces; or, as shown in FIG. 3, the first sidewall 51 and the second sidewall 61 may be concave curved surfaces. Compared with a solution in which both the first sidewall 51 and the second sidewall 61 are slanted flat surfaces, that the first sidewall 51 and the second sidewall 61 are curved surfaces can further increase the contact area between the first N-type heavily doped layer 50 and the channel structure 20 and the contact area between the second N-type heavily doped layer 60 and the channel structure 20. It further contributes to reducing the contact resistance R1a between the first N-type heavily doped layer 50 and the two-dimensional electron gas and the contact resistance Rib between the second N-type heavily doped layer 60 and the two-dimensional electron gas, thereby reducing the overall contact resistance in the semiconductor structure. In some embodiments of the present disclosure, the semiconductor structure further includes a gate electrode 70, a source electrode 80 and a drain electrode 90.

Optionally, as shown in FIG. 4, the gate electrode 70 is disposed at a side of the barrier layer 22 away from the substrate 10. A gate dielectric layer 71 may be disposed between the gate electrode 70 and the barrier layer 22. A source electrode 80 is electrically connected to a first surface 53 of the first N-type heavily doped layer 50 away from the substrate 10. A drain electrode 90 is electrically connected to a second surface 63 of the second N-type heavily doped layer 60 away from the substrate 10. The first surface 53 and the second surface 63 are rough surfaces. The roughness of the rough surface may be determined according to the resistivity and/or the thickness of the first N-type heavily doped layer 50 and the second N-type heavily doped layer 60.

The contact resistance of the semiconductor structure further includes a contact resistance R3a between the source electrode 80 and the first N-type heavily doped layer 50 and a contact resistance R3b between the drain electrode 90 and the second N-type heavily doped layer 60. The contact resistance R3a between the source electrode 80 and the first N-type heavily doped layer 50, the body resistance R2a of the first N-type heavily doped layer 50, the contact resistance R1a between the first N-type heavily doped layer 50 and the channel structure 20, the contact resistance R1b between the second N-type heavily doped layer 60 and the channel structure 20, the body resistance R2b of the second N-type heavily doped layer 60 and the contact resistance R3b between the drain electrode 90 and the second N-type heavily doped layer 60 are sequentially connected in series.

In this embodiment, without changing the sizes of the source electrode 80 and the drain electrode 90, the first surface 53 and the second surface 63 for respectively contacting the source electrode 80 and the drain electrode 90 are provided as rough surfaces, so that the contact area between the source electrode 80 and the first N-type heavily doped layer 50 and the contact area between the drain electrode 90 and the second N-type heavily doped layer 60 are both increased, which can reduce the ohmic contact resistance between the source electrode 80 and the first N-type heavily doped layer 50 and the ohmic contact resistance between the drain electrode 90 and the second N-type heavily doped layer 60, thereby reducing the overall contact resistance in the semiconductor structure. In addition, a certain roughness may result in that the transmission path of the current between the two-dimensional electron gas and the electrode is shortened, thereby reducing the influence of the bulk resistance of the first N-type heavily doped layer 50 and the second N-type heavily doped layer 60.

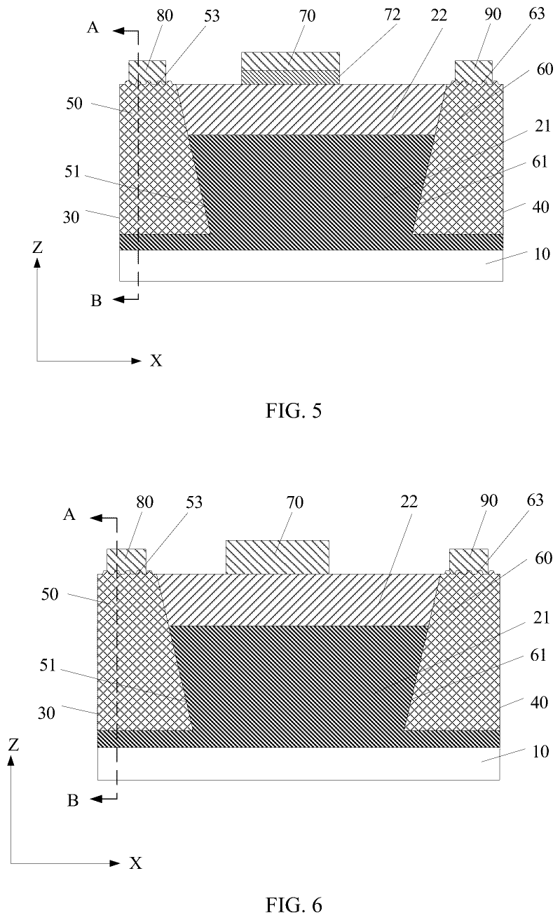

It should be noted that, the semiconductor structure according to the present disclosure may be applied to diverse types of HEMT devices, for example, as shown in FIG. 5, it may be used to form an enhancement-mode high electron mobility transistor (E-MODE HEMT). Specifically, the difference between the structure shown in FIG. 5 and the structure shown in FIG. 4 includes that no gate dielectric layer 71 is disposed between the gate electrode 70 and the barrier layer 22, and a P-type GaN layer 72 is disposed between the gate electrode 70 and the barrier layer 22. The P-type GaN layer 72 may deplete electrons in the 2 DEG to form an enhancement mode structure. The structure shown in FIG. 5 has a similar effect as the structure shown in FIG. 4, and therefore, details will not be repeated herein.

Optionally, the semiconductor structure of the present disclosure may be the structure shown in FIG. 6, and the difference between the structure shown in FIG. 6 and the structure shown in FIG. 4 includes that no gate dielectric layer 71 is provided between the gate electrode 70 and the barrier layer 22, and in this case, a Schottky contact is provided between the gate electrode 70 and the barrier layer 22. The structure shown in FIG. 6 has a similar effect as the structure shown in FIG. 4, and therefore, details will not be repeated herein.

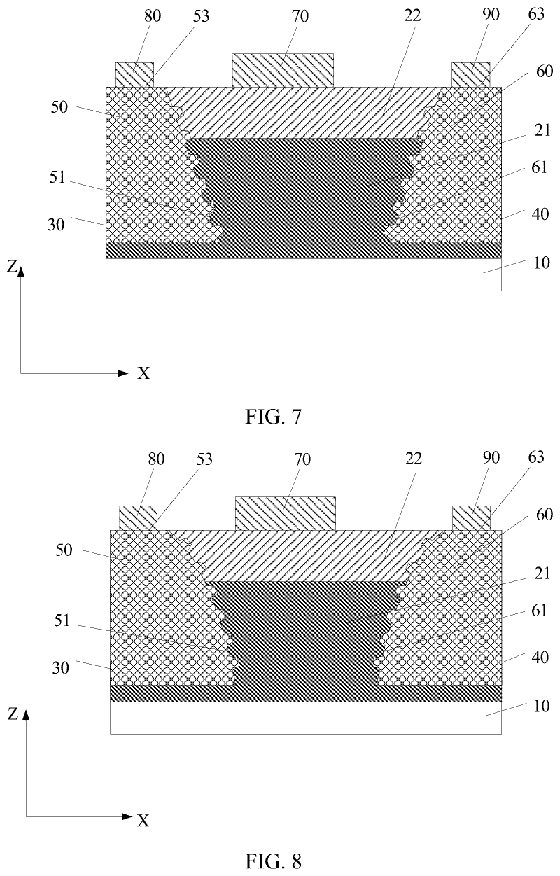

In some embodiments of the present disclosure, as shown in FIG. 7, the difference between the semiconductor structure in this embodiment and the structure shown in FIG. 6 includes that the first sidewall 51 and the second sidewall 61 may be rough surfaces. Compared with the first sidewall 51 and the second sidewall 61 which are both smooth surfaces shown in FIGS. 1 to 3, that the first sidewall 51 and the second sidewall 61 are rough surfaces can further increase the contact area between the first N-type heavily doped layer 50 and the channel structure 20 and the contact area between the second N-type heavily doped layer 60 and the channel structure 20. It further contributes to reducing the contact resistance R1a between the first N-type heavily doped layer 50 and the two-dimensional electron gas and the contact resistance R1b between the second N-type heavily doped layer 60 and the two-dimensional electron gas, thereby reducing the overall contact resistance in the semiconductor structure.

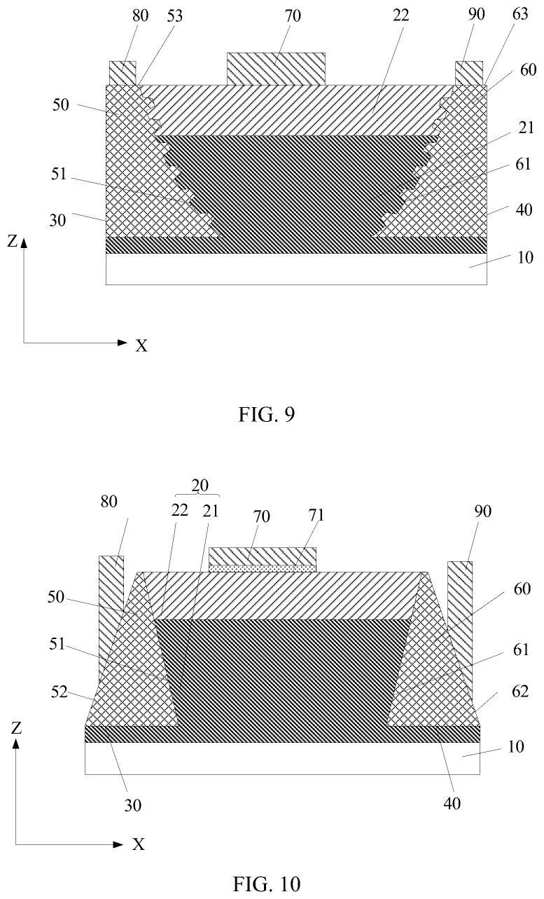

It should be noted that the first sidewall 51 and the second sidewall 61 may be rough surfaces while being convex surfaces or concave surfaces. For example, as shown in FIGS. 8 and 9, such structures can contribute to reducing the contact resistance R1a between the first N-type heavily doped layer 50 and the two-dimensional electron gas and the contact resistance Rib between the second N-type heavily doped layer 60 and the two-dimensional electron gas.

Optionally, as shown in FIG. 10, the gate electrode 70 is disposed at a side of the barrier layer 22 away from the substrate 10. A source electrode 80 is electrically connected to a third sidewall 52 of the first N-type heavily doped layer 50 away from the gate region 11. A drain electrode 90 is electrically connected to a fourth sidewall 62 of the second N-type heavily doped layer 60 away from the gate region 11. In a direction away from the substrate 10, distances between the third sidewall 52 and the fourth sidewall 62 gradually decrease. That is, in the direction away from the substrate 10, the third sidewall 52 and the fourth sidewall 62 are both inclined slopes toward the gate region 11. The angle between the third sidewall 52 and the plane where the substrate 10 is located and the angle between the fourth sidewall 62 and the plane where the substrate 10 is located may range from 30 degrees to 70 degrees, for example, 65 degrees, 50 degrees, 45 degrees, or 35 degrees. That is, in the cross section where the X-axis and the Z-axis are located, the shapes of the first N-type heavily doped layer 50 and the second N-type heavily doped layer 60 are triangles or trapezoids that are narrow at the top and wide at the bottom.

In this way, the current path can be shortened, and the influence of the bulk resistance of the first N-type heavily doped layer 50 and the second N-type heavily doped layer 60 can be reduced. Therefore, the overall resistance of the semiconductor structure is reduced.

In this embodiment, without changing the sizes, such as length and width, of the source electrode 80 and the drain electrode 90, the third sidewall 52 and the fourth sidewall 62 are both arranged as slanted surfaces, so that the contact area between the source electrode 80 and the first N-type heavily doped layer 50 and the contact area between the drain electrode 90 and the second N-type heavily doped layer 60 are both increased, which can reduce the contact resistance between the source electrode 80 and the first N-type heavily doped layer 50 and the contact resistance between the drain electrode 90 and the second N-type heavily doped layer 60, thereby reducing the overall contact resistance in the semiconductor structure.

In some embodiments of the present disclosure, the third sidewall 52 and the fourth sidewall 62 may be curved surfaces, for example, convex curved surfaces or concave curved surfaces.

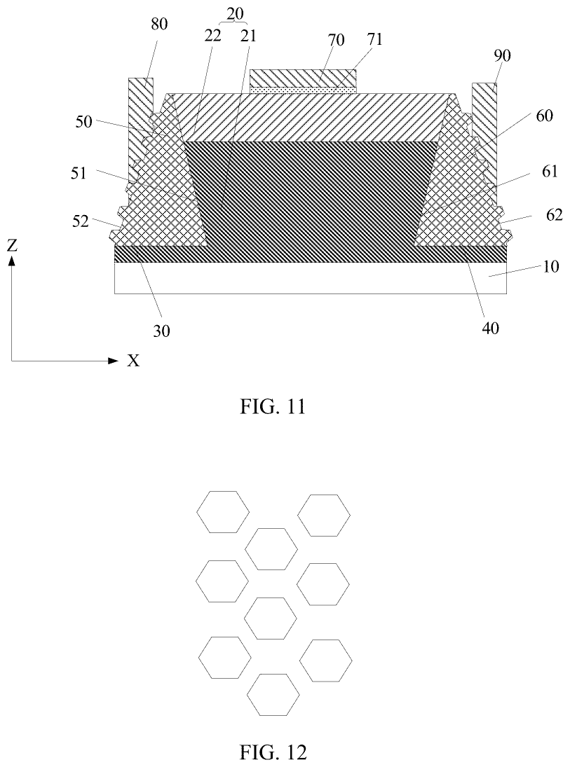

Further, as shown in FIG. 11, the third sidewall 52 and the fourth sidewall 62 are respectively the rough surfaces. The third sidewall 52 and the fourth sidewall 62 are both contact surfaces, and the third sidewall 52 and the fourth sidewall 62 are both arranged as the rough surfaces, which can further increase the contact area between the source electrode 80 and the first N-type heavily doped layer 50 and the contact area between the drain electrode 90 and the second N-type heavily doped layer 60, thereby reducing the contact resistance between the source electrode 80 and the first N-type heavily doped layer 50 and the contact resistance between the drain electrode 90 and the second N-type heavily doped layer 60, and further reducing the overall contact resistance in the semiconductor structure.

Optionally, the first sidewall 51 and the second sidewall 61 in the structure shown in FIG. 11 may be rough surfaces while being convex surfaces or concave surfaces. Therefore, on the basis that the semiconductor structure shown in FIG. 11 can reduce the contact resistance between the source electrode 80 and the first N-type heavily doped layer 50 and the contact resistance between the drain electrode 90 and the second N-type heavily doped layer 60, the contact resistance R1a between the first N-type heavily doped layer 50 and the two-dimensional electron gas and the contact resistance R1b between the second N-type heavily doped layer 60 and the two-dimensional electron gas are further reduced.

In some embodiments of the present disclosure, the first N-type heavily doped layer 50 and the second N-type heavily doped layer 60 each includes any one of an N-type heavily doped GaN-based material layer or an N-type heavily doped GaN-based superlattice structure.

For example, the GaN-based superlattice structure may be a superlattice structure formed by GaN layers and AlGaN layers which are stacked alternately in period, or a superlattice structure formed by GaN layers and InGaN layers which are stacked alternately in period. By introducing the superlattice structure, the sheet resistance of the first N-type heavily doped layer 50 and the second N-type heavily doped layer 60 can be further reduced.

For example, the first N-type heavily doped layer 50 and the second N-type heavily doped layer 60 are made of GaN-based materials, and crystal plane indices of the first sidewall 51 and the second sidewall 61 respectively include at least one of (112̅3), (112̅2), (112̅1), (101̅2), (101̅1) or (202̅1).

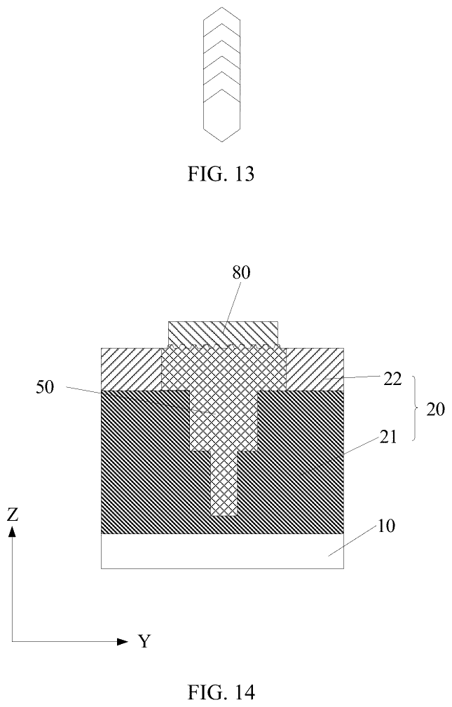

Optionally, the crystal plane indices of the third sidewall 52 and the fourth sidewall 62 respectively include at least one of (112̅3), (112̅2), (112̅1), (101̅2), (101̅1) or (202̅1). For example, as shown in FIG. 12, when the crystal plane indices of the third sidewall 52 and the fourth sidewall 62 are (112̅3), the surfaces of the third sidewall 52 and the fourth sidewall 62 respectively include a plurality of hexagons which are spaced apart or in contact; or as shown in FIG. 13, the crystal plane indices of the third sidewall 52 and the fourth sidewall 62 are (101̅2), and the surfaces of the third sidewall 52 and the fourth sidewall 62 respectively include a plurality of hexagons which are stacked in sequence.

In some embodiments of the present disclosure, the N-type element doped in the first N-type heavily doped layer 50 and the second N-type heavily doped layer 60 may include at least one of Si, Ge, Sn, Se, or Te. The doping concentration of the N-type element may be greater than 1E18/cm³. The higher the doping concentration of the N-type element, the lower the contact resistance between the first N-type heavily doped layer 50 and the source electrode 80 and the contact resistance between the second N-type heavily doped layer 60 and the drain electrode 90.

In some embodiments of the present disclosure, as shown in FIGS. 1 to 8, in the cross section, the first sidewall 51 and the second sidewall 61 are symmetrically disposed, and the first N-type heavily doped layer 50 and the second N-type heavily doped layer 60 are symmetrically disposed. That is, the channel structure 20 is a symmetrical pattern, and at the same height, the distance from the first sidewall 51 to the symmetry axis of the channel structure 20 is the same as the distance from the second sidewall 61 to the symmetry axis of the channel structure 20, so that the distribution of the current can be more uniform, thereby improving the reliability of the semiconductor structure.

FIG. 14 is a schematic diagram of a cross-section along line AB in FIGS. 4 to 6. In some embodiments of the present disclosure, as shown in FIG. 14, in the direction away from the substrate 10, the widths of the cross section of the first N-type heavily doped layer 50 perpendicular to the channel length direction, that is, the cross section of the first N-type heavily doped layer 50 where the Y-axis and the Z-axis are located, gradually increase. In some embodiments of the present disclosure, the structure of the second N-type heavily doped layer 60 is similar to the structure of the first N-type heavily doped layer 50, and in the direction away from the substrate 10, the widths of the cross section of the second N-type heavily doped layer 60 perpendicular to the channel length direction, that is, the cross section of the second N-type heavily doped layer 60 where the Y-axis and the Z-axis are located, gradually increase.

For example, a gradual increase of the widths of the cross section of the first N-type heavily doped layer 50 perpendicular to a channel length direction includes a linear increase, a curvilinear increase or a stepped increase. For another example, a gradual increase of the widths of the cross section of the second N-type heavily doped layer 60 perpendicular to the channel length direction includes a linear increase, a curvilinear increase or a stepped increase. For example, the curve mentioned in the curvilinear increase may refer to a parabola, a wavy line, an arc, or the like.

In a direction away from the substrate 10, the widths of cross sections of the first N-type heavily doped layer 50 and the second N-type heavily doped layer 60 in a direction perpendicular to the channel length direction gradually increase, so that the contact area between the first N-type heavily doped layer 50 and the channel structure 20 and the contact area between the second N-type heavily doped layer 60 and the channel structure 20 in the direction perpendicular to the channel length can be increased, thereby reducing the contact resistance between the first N-type heavily doped layer 50 and the channel structure 20 and the contact resistance between the second N-type heavily doped layer 60 and the channel structure 20. In addition, such structure reduces the volume of the first N-type heavily doped layer 50, and may further reduce the body resistance of the first N-type heavily doped layer 50.

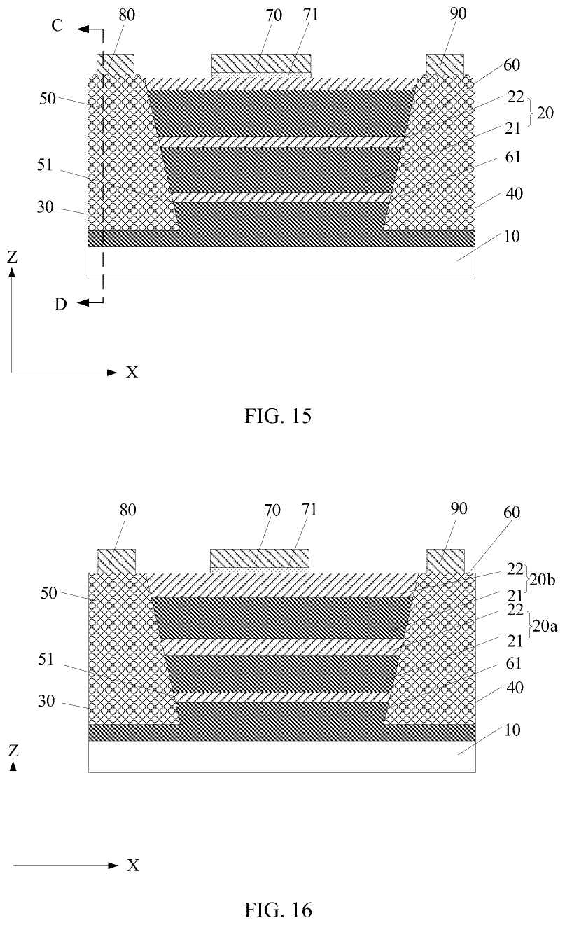

In some embodiments of the present disclosure, as shown in FIG. 15, the semiconductor structure includes a plurality of channel structures 20 stacked on the substrate 10 sequentially, and the bottom surface of the first groove 30 and the bottom surface of the second groove 40 are respectively lower than a surface of the channel layer 21 away from the substrate 10 in a channel structure 20 closest to the substrate 10. The bottom surface of the first groove 30 and the bottom surface of the second groove 40 are respectively higher than a surface of the channel layer 21 toward the substrate 10 in the channel structure 20 closest to the substrate 10, so that breakdown of the substrate 10 can be avoided; and the bottom surface of the first groove 30 and the bottom surface of the second groove 40 are respectively lower than a surface of the channel layer 21 away from the substrate 10 in a channel structure 20 closest to the substrate 10, so that the current can be prevented from being concentrated in the channel structures 20 that are away from the substrate 10, and the current is evenly distributed in the channel structures 20.

In the direction away from the substrate 10, the average Al contents of the barrier layers 22 in the plurality of channel structures 20 gradually increase or gradually decrease. Optionally, the average Al contents of the barrier layers 22 in the plurality of channel structures 20 gradually increase, and in the plurality of groups of stacked structures, the average Al content of the barrier layer 22 away from the substrate 10 is greater than the average Al content of the barrier layer 22 closer to the substrate 10, to gradually reduce the stress influence of the heterojunction substrate.

In some embodiments of the present disclosure, as shown in FIG. 16, in the direction away from the substrate 10, the thickness of the channel structure 20a which is closer to the substrate 10 is less than the thickness of the channel structure 20b which is away from the substrate 10. That is, in the direction away from the substrate 10, the thicknesses of the plurality of channel structures 20 gradually increase, so that the stress can be gradually released, thereby further reducing the influence of the stress of the heterojunction substrate on the performance of the HEMT device.

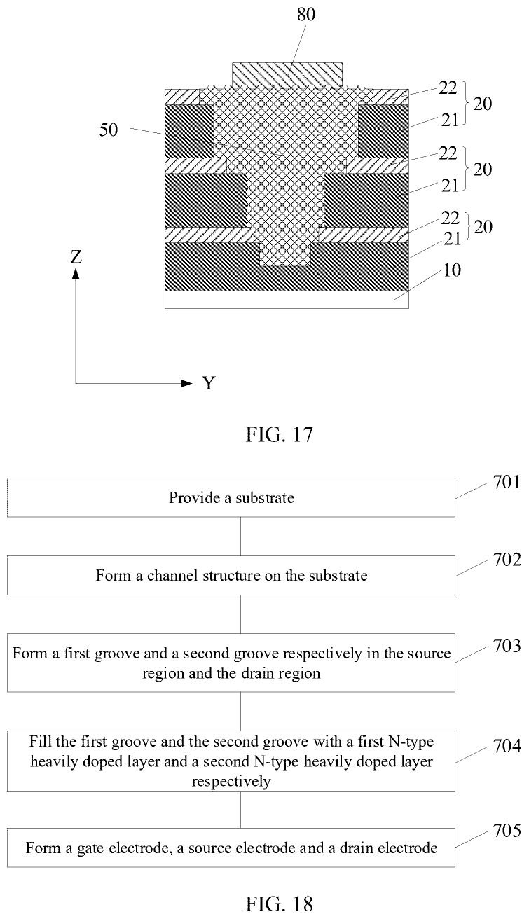

FIG. 17 is a schematic diagram of a cross-section along the line CD in FIG. 15, which is a schematic diagram of a cross-section of the semiconductor structure perpendicular to the channel length shown in FIG. 15. In some embodiments of the present disclosure, as shown in FIG. 17, the semiconductor structure includes a plurality of channel structures 20 stacked on the substrate 10 sequentially, and in a direction away from the substrate 10, the widths of the cross section of the first N-type heavily doped layer 50 perpendicular to the channel length direction increase in a stepped manner, and an interface between the barrier layer 22 and the channel layer 21 of each channel structure 20 is flush with a stepped surface of the first N-type heavily doped layer 50. It contributes to connecting the first N-type heavily doped layer 50 to the two-dimensional electron gas in the channel structure 20, and effectively reducing the ohmic contact resistance, thereby reducing the overall contact resistance in the semiconductor structure.

In some embodiments of the present disclosure, in the cross-sectional direction parallel to the cross-section of FIG. 17, the schematic diagram of a cross section of the second N-type heavily doped layer 60 is similar to the schematic diagram of the cross section of the first N-type heavily doped layer 50 in FIG. 17, and has similar technical effects, which will not be repeated herein. As shown in FIG. 18, according to the present disclosure, a method for manufacturing a semiconductor structure is provided, and the method includes the following steps.

In step 701: a substrate 10 is provided.

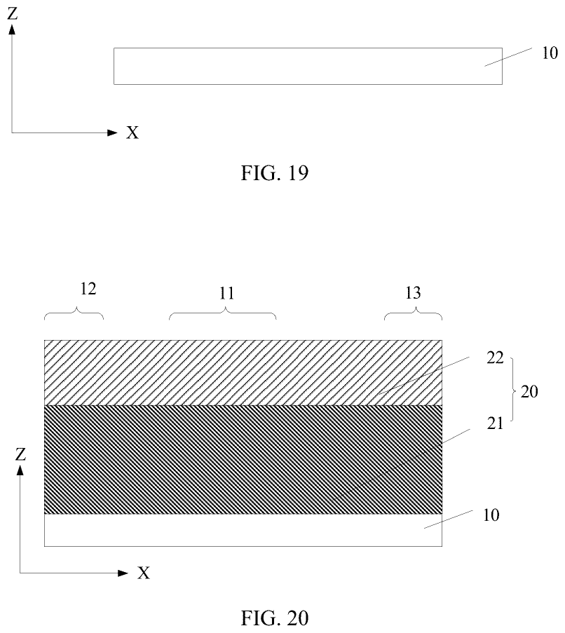

As shown in FIG. 19, in some embodiments of the present disclosure, the substrate 10 may be made of a semiconductor or an oxide, the semiconductor may include silicon (Si), gallium nitride (GaN), silicon carbide (SiC), or gallium arsenide (GaAs), and the oxide may include sapphire. For example, the substrate 10 in this embodiment may be made of silicon carbide.

In step 702: a channel structure 20 on the substrate 10 is formed. Forming the channel structure 20 on the substrate 10 includes forming a channel layer 21 on the substrate 10 and forming a barrier layer 22 on the channel layer 21, where the channel structure 20 includes a gate region 11, and a source region 12 and a drain region 13 at both sides of the gate region 11.

As shown in FIG. 20, the channel layer 21 and the barrier layer 22 may be made of III-V group semiconductor materials, for example, the channel layer 21 is made of GaN, the barrier layer 22 is made of AlGaN, and 2 DEG is formed between the channel layer 21 and the barrier layer 22 which are made of different GaN-based compounds by using a polarization effect.

The channel layer 21 and the barrier layer 22 may be formed by atomic layer deposition (ALD), chemical vapor deposition (CVD), molecular beam epitaxy (MBE), plasma enhanced chemical vapor deposition (PECVD), low pressure chemical vapor deposition (LPCVD), physical vapor deposition (PVD), metal-organic molecular beam epitaxy (MOMBE), metal-organic chemical vapor deposition (MOCVD), or a combination thereof.

In step 703: a first groove 30 and a second groove 40 are formed in the source region 12 and the drain region 13, respectively. A bottom surface of the first groove 30 and a bottom surface of the second groove 40 are respectively lower than a surface of the channel layer 21 away from the substrate 10; and in a direction away from the substrate 10, distances between the first inner wall 31 of the first groove 30 toward the gate region 11 and the second inner wall 41 of the second groove 40 toward the gate region 11 gradually increase.

As shown in FIG. 21, the cross sections where the X-axis and the Z-axis are located of the first groove 30 and the second groove 40 are narrow at the top and wide at the bottom, and the first inner wall 31 and the second inner wall 41 are slanted in a direction away from the gate region 11 of the channel structure 20. The first groove 30 and the second groove 40 may be formed by anisotropic etching, such as dry etching or wet etching. Bottom surfaces of the first groove 30 and the second groove 40 are higher than a surface of the channel layer 21 toward the substrate 10 and lower than the surface of the channel layer 21 away from the substrate 10. The surfaces of the first inner wall 31 and the second inner wall 41 may be rough surfaces.

In step 704, the first groove 30 and the second groove 40 are filled with the first N-type heavily doped layer 50 and the second N-type heavily doped layer 60 respectively. In a direction away from the substrate 10, distances between the first sidewall 51 of the first N-type heavily doped layer 50 toward the gate region 11 and the second sidewall 61 of the second N-type heavily doped layer 60 toward the gate region 11 gradually increase.

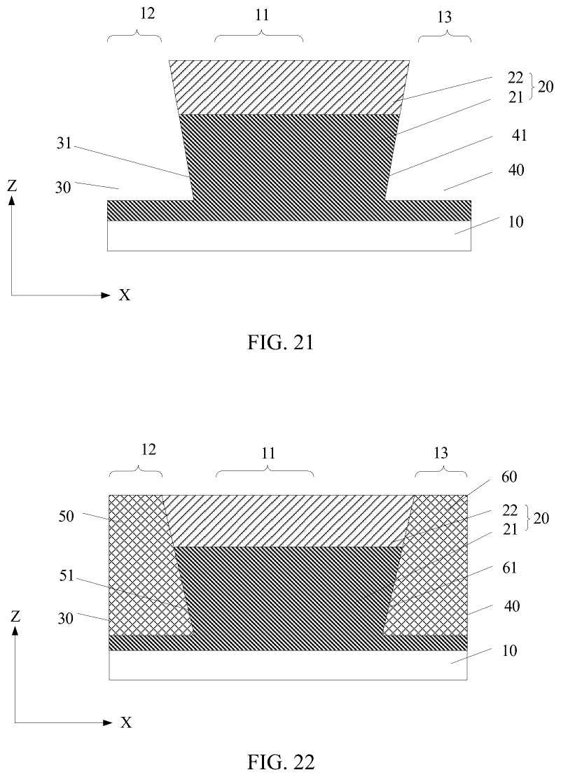

As shown in FIG. 22, a selected area growth (SAG) process may be used to form the first N-type heavily doped layer 50 and the second N-type heavily doped layer 60 in the first groove 30 and the second groove 40, respectively. The first N-type heavily doped layer 50 and the second N-type heavily doped layer 60 are made of N-type heavily doped GaN-based materials. The N-type element doped in the first N-type heavily doped layer 50 and the second N-type heavily doped layer 60 may include at least one of Si, Ge, Sn, Se, or Te. The doping concentration of the N-type element may be greater than 1E18/cm³.

In some embodiments, the method for manufacturing the semiconductor structure may further include:
step 705: a gate electrode 70, a source electrode 80 and a drain electrode 90 are formed.

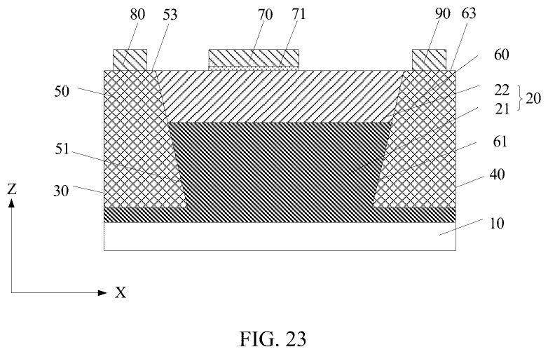

As shown in FIG. 23, the gate electrode 70 is disposed at a side of the barrier layer 22 away from the substrate 10. A gate dielectric layer 71 may be disposed between the gate electrode 70 and the barrier layer 22. A source electrode 80 is electrically connected to a first surface 53 of the first N-type heavily doped layer 50 away from the substrate 10. A drain electrode 90 is electrically connected to a second surface 63 of the second N-type heavily doped layer 60 away from the substrate 10.

The manufacturing method of the semiconductor structure in this embodiment has the same inventive concept and the similar beneficial effects as the semiconductor structure, and details not described in this embodiment may refer to the above embodiments of the semiconductor structure.

The above description are some embodiments of the present disclosure and is not intended to limit the present disclosure, and any modifications, equivalent substitutions, improvements and the like made within the spirit and the principle of the present disclosure shall fall within the protection scope of the present disclosure.

What is claimed is:

1. A semiconductor structure, comprising:
a substrate and a channel structure on the substrate, wherein the channel structure comprises a channel layer on the substrate and a barrier layer on the channel layer, and the channel structure comprises a gate region, and a source region and a drain region at both sides of the gate region;
wherein the source region is provided with a first groove, the drain region is provided with a second groove, a bottom surface of the first groove and a bottom surface of the second groove are lower than a surface of the channel layer away from the substrate, the first groove is filled with a first N-type heavily doped layer, the second groove is filled with a second N-type heavily doped layer, and in a direction away from the substrate, distances between a first sidewall of the first N-type heavily doped layer toward the gate region and a second sidewall of the second N-type heavily doped layer toward the gate region gradually increase.

2. The semiconductor structure according to claim 1, wherein the first N-type heavily doped layer comprises a third sidewall away from the gate region, and the second N-type heavily doped layer comprises a fourth sidewall away from the gate region;
wherein in the direction away from the substrate, distances between the third sidewall and the fourth sidewall gradually decrease.

3. The semiconductor structure according to claim 2, wherein the third sidewall and the fourth sidewall are respectively rough surfaces.

4. The semiconductor structure according to claim 2, further comprising:
a gate electrode, at a side of the barrier layer away from the substrate;
a source electrode, electrically connected to the third sidewall; and
a drain electrode, electrically connected to the fourth sidewall.

5. The semiconductor structure according to claim 1, wherein each of the first sidewall and the second sidewall is configured as an inclined flat surface, a convex curved surface, or a concave curved surface.

6. The semiconductor structure according to claim 1, wherein the first sidewall and the second sidewall are respectively rough surfaces.

7. The semiconductor structure according to claim 1, further comprising:
a gate electrode, at a side of the barrier layer away from the substrate;
a source electrode, electrically connected to a first surface of the first N-type heavily doped layer away from the substrate; and
a drain electrode, electrically connected to a second surface of the second N-type heavily doped layer away from the substrate;
wherein the first surface and the second surface are rough surfaces.

8. The semiconductor structure according to claim 1, wherein the first N-type heavily doped layer and the second N-type heavily doped layer each comprises an N-type heavily doped GaN-based material layer or an N-type heavily doped GaN-based superlattice structure.

9. The semiconductor structure according to claim 1, wherein the first sidewall is axially symmetrical to the second sidewall, and the first N-type heavily doped layer is axially symmetrical to the second N-type heavily doped layer.

10. The semiconductor structure according to claim 1, wherein in the direction remote from the substrate, widths of a cross section of the first N-type heavily doped layer perpendicular to a channel length direction gradually increase; and/or in the direction away from the substrate, widths of a cross section of the second N-type heavily doped layer perpendicular to the channel length direction gradually increase.

11. The semiconductor structure according to claim 10, wherein a gradual increase of the widths of the cross section of the first N-type heavily doped layer perpendicular to the channel length direction comprises a linear increase, a curvilinear increase or a stepped increase; and/or a gradual increase of the widths of the cross section of the second N-type heavily doped layer perpendicular to the channel length direction comprises a linear increase, a curvilinear increase or a stepped increase.

12. The semiconductor structure according to claim 1, wherein the semiconductor structure comprises a plurality of channel structures stacked on the substrate sequentially, and the bottom surface of the first groove and the bottom surface of the second groove are respectively lower than a surface of a channel layer away from the substrate in one of the plurality of channel structures closest to the substrate.

13. The semiconductor structure according to claim 12, wherein in the direction away from the substrate, average Al contents of barrier layers in the plurality of channel structures gradually decrease.

14. The semiconductor structure according to claim 1, wherein the first N-type heavily doped layer and the second N-type heavily doped layer are made of GaN-based materials, and crystal plane indices of the first sidewall and the second sidewall each independently comprises at least one of (112̅3), (112̅2), (112̅1), (101̅2), (101̅1) or (202̅1).

15. A method for manufacturing the semiconductor structure of claim 1, comprising:
providing the substrate;
forming the channel structure on the substrate, wherein forming the channel structure comprises forming the channel layer on the substrate and forming the barrier layer on the channel layer, and the channel structure comprises the gate region, and the source region and the drain region at both sides of the gate region;
forming the first groove and the second groove respectively in the source region and the drain region, wherein the bottom surface of the first groove and the bottom surface of the second groove are respectively lower than the surface of the channel layer away from the substrate; and in the direction away from the substrate, distances between the first inner wall of the first groove toward the gate region and the second inner wall of the second groove toward the gate region gradually increase; and
filling the first groove and the second groove with the first N-type heavily doped layer and the second N-type heavily doped layer respectively, wherein in the direction away from the substrate, the distances between the first sidewall of the first N-type heavily doped layer toward the gate region and the second sidewall of the second N-type heavily doped layer toward the gate region gradually increase.

16. The method according to claim 15, further comprising:
etching the first N-type heavily doped layer and the second N-type heavily doped layer to form a third sidewall of the first N-type heavily doped layer away from the gate region and a fourth sidewall of the second N-type heavily doped layer away from the gate region, wherein in the direction away from the substrate, distances between the third sidewall and the fourth sidewall gradually decrease;
forming a gate electrode at a side of the barrier layer away from the substrate; and
forming a source electrode electrically connected to the third sidewall and a drain electrode electrically connected to the fourth sidewall.

17. The method according to claim 16, wherein after etching the first N-type heavily doped layer and the second N-type heavily doped layer, the method further comprises: roughening the third sidewall and the fourth sidewall.

18. The method according to claim 15, wherein a first surface of the first N-type heavily doped layer away from the substrate is a rough surface, and a second surface of the second N-type heavily doped layer away from the substrate is a rough surface, and the method further comprises:
forming a gate electrode at a side of the barrier layer away from the substrate; and
forming a source electrode electrically connected to the first surface and a drain electrode electrically connected to the second surface.

19. The method according to claim 15, wherein
forming the first groove and the second groove respectively in the source region and the drain region comprises:
respectively forming the first groove and the second groove each having a cross section perpendicular to a channel length direction whose widths gradually increase in the direction away from the substrate; and
filling the first groove and the second groove with the first N-type heavily doped layer and the second N-type heavily doped layer respectively comprises:
forming the first N-type heavily doped layer and/or the second N-type heavily doped layer, wherein widths of a cross section of the first N-type heavily doped layer perpendicular to the channel length direction and widths of a cross section of the second N-type heavily doped layer perpendicular to the channel length direction gradually increase respectively.

20. The method according to claim 15, wherein
forming the channel structure on the substrate comprises:
forming a plurality of channel structures stacked on the substrate sequentially; and
forming the first groove and the second groove respectively in the source region and the drain region comprises:
etching the plurality of channel structures until that the bottom surface of the first groove and the bottom surface of the second groove are respectively lower than a surface of the channel layer away from the substrate in one of the plurality of channel structures closest to the substrate.
